(19) United States
(12) Patent Application Publication
(10) Pub. No.: US 2009/0038679 A1
(43) Pub. Date: Feb. 12, 2009

(54) Thin Multijunction Solar Cells With Plated Metal OHMIC Contact and Support

(75) Inventors: Tansen Varghese, Albuquerque, NM (US); Arthur Cornfeld, Sandia Park, NM (US); Michelle Xie, Sandia Park, NM (US)

Correspondence Address: Casey Toohey;Emcore Corporation, 1600 Eubank Blvd., SE, Albuquerque, NM, 87123, US

(73) Assignee: Emcore Corporation, Somerset, NJ (US)

(21) Appl. No.: 11/836,402

(22) Filed: Aug. 9, 2007

(51) Int. Cl. H01L 31/042; H01L 21/62

(52) U.S. Cl. 136/256; 438/73; 257/E31.093; 257/E21.52

(57) ABSTRACT

A method of forming a thin multifunction solar cell in which an electroplating process is used to form a thick metal layer to give strength and support to the solar cell. The strain of the plated thick metal layer is adjusted during the process by parameter control to compensate for the strain in the other device layers, so that the curvature of the thin device can be eliminated or otherwise controlled.

### REFERENCE TO RELATED APPLICATIONS

This application is related to co-pending U.S. patent application Ser. No. 11/616,596 filed Dec. 27, 2006.

This application is also related to co-pending U.S. patent application Ser. No. 11/445,793 filed Jun. 2, 2006.

### GOVERNMENT RIGHTS STATEMENT

This invention was made with government support under Contract No. FA9453-04-2-0041 awarded by the U.S. Air Force. The Government has certain rights in the invention.

### BACKGROUND OF THE INVENTION

1. Field of the Invention

The present invention relates to the field of solar cell semiconductor devices, and particularly to integrated semiconductor structures including a multijunction solar cell including an electroplated ohmic contact.

2. Description of the Related Art

Photovoltaic cells, also called solar cells, are one of the most important new energy sources that have become available in the past several years. Considerable effort has gone into solar cell development. As a result, solar cells are currently being used in a number of commercial and consumer-oriented applications. While significant progress has been made in this area, the requirement for solar cells to meet the needs of more sophisticated applications has not kept pace with demand. Applications such as satellites used in data communications have dramatically increased the demand for solar cells with improved power and energy conversion characteristics.

In satellite and other space related applications, the size, mass and cost of a satellite power system are dependent on the power and energy conversion efficiency of the solar cells used. Putting it another way, the size of the payload and the availability of on-board services are proportional to the amount of power provided. Thus, as the payloads become more sophisticated, solar cells, which act as the power conversion devices for the on-board power systems, become increasingly more important.

Solar cells are often fabricated in vertical, multifunction structures, and disposed in horizontal arrays, with the individual solar cells connected together in a series. The shape and structure of an array, as well as the number of cells it contains, are determined in part by the desired output voltage and current.

Occasionally, there is a need to reduce the thickness of wafers and devices. For example, in photodiodes, reducing the thickness of the substrate reduces the heat-conducting path, and enables the photodiode to handle more light at high speed. In space photovoltaics, the advantage to reducing the thickness is reduction of the payload weight at launch.

Thinning the substrate means that some other means of support has to be given to the device layers, during processing, and in use. Also, any residual strain (from growth, thermal mismatch, etc.) in the device layers will present itself as curvature in the layers, which can be corrected by incorporating strain of the opposite sign in the support that's given to the layers, while still keeping it flexible for conformal attachment to a curved surface. Inverted metamorphic solar cell structures such as described in U.S. Pat. No. 6,951,819 and M. W. Wanless et al., Lattice Mismatched Approaches for High Performance, III-V Photovoltaic Energy Converters (Conference Proceedings of the 31^{st} IEEE Photovoltaic Specialists Conference, Jan. 3-7, 2005, IEEE Press, 2005) present one approach to thinning the substrate in a solar cell. The structures described in such prior art present a number of practical difficulties relating to the appropriate choice of materials and fabrication steps.

Prior to the present invention, the materials and fabrication steps disclosed in the prior art have not been adequate to produce a commercially viable, manufacturable, and energy efficient solar cell.

### SUMMARY OF THE INVENTION

### 1. Objects of the Invention

It is an object of the present invention to provide an improved multijunction solar cell.

It is an object of the invention to provide an improved inverted metamorphic solar cell.

It is still another object of the invention to provide a method of manufacturing an inverted metamorphic solar cell as a thin, flexible film.

Additional objects, advantages, and novel features of the present invention will become apparent to those skilled in the art from this disclosure, including the following detailed description as well as by practice of the invention. While the invention is described below with reference to preferred embodiments, it should be understood that the invention is not limited thereto. Those of ordinary skill in the art having access to the teachings herein will recognize additional applications, modifications and embodiments in other fields, which are within the scope of the invention as disclosed and claimed herein and with respect to which the invention could be of utility.

### 2. Features of the Invention

Briefly, and in general terms, the present invention provides a solar cell that includes a first substrate; depositing on the first substrate a sequence of layers of semiconductor material forming a solar cell; forming an ohmic contact layer on the solar cell; and electroplating a metallic contact layer over said ohmic contact layer.

In another aspect, the present invention provides a solar cell that includes a semiconductor body having a sequence of layers including a first solar subcell having a first band gap; a second solar subcell disposed over the first subcell and having a second band gap smaller than the first band gap; a grading interlayer disposed over the second subcell and having a third band gap larger than the second ban gap; a third subcell disposed over the interlayer such that the third solar subcell is lattice mismatched with respect to the second subcell and has a fourth band gap smaller than the third band gap; and an electroplated contact layer disposed over said third subcell.

### BRIEF DESCRIPTION OF THE DRAWINGS

These and other features and advantages of this invention will be better and more fully appreciated by reference to the following detailed description when considered in conjunction with the accompanying drawings, wherein:

FIG. 1 is an enlarged cross-sectional view of the solar cell according to the present invention at the end of the process steps of forming the layers of the solar cell;

FIG. 2 is a cross-sectional view of the solar cell of FIG. 1 after the next process step according to the present invention;

FIG. 3 is a cross-sectional view of the solar cell of FIG. 2 after the next process step according to the present invention;

FIG. 4 is a cross-sectional view of the solar cell of FIG. 3 after the next process step according to the present invention in which an adhesive is applied;

FIG. 5A is a cross-sectional view of the solar cell of FIG. 4 after the next process step according to the present invention in which a surrogate substrate is attached;

FIG. 5B is another cross-sectional view of the solar cell of FIG. 4 after the next process step according to the present invention in which the original substrate is removed;

FIG. 6A is a top plan view of a wafer in which the solar cells according to the present invention are fabricated;

FIG. 6B is a bottom plan view of a wafer in which the solar cells according to the present invention are fabricated;

FIG. 7 is a top plan view of the wafer of FIG. 6B after the next process step according to the present invention;

FIG. 8 is a cross-sectional view of the solar cell of FIG. 5B after the next process step according to the present invention;

FIG. 9 is a cross-sectional view of the solar cell of FIG. 8 after the next process step according to the present invention;

FIG. 10 is a cross-sectional view of the solar cell of FIG. 9 after the next process step according to the present invention;

FIG. 11 is a cross-sectional view of the solar cell of FIG. 10 after the next process step according to the present invention;

FIG. 12 is a cross-sectional view of the solar cell of FIG. 11 after the next process step according to the present invention;

FIG. 13 is a cross-sectional view of the solar cell of FIG. 12 after the next process step according to the present invention;

FIG. 14 is a cross-sectional view of the solar cell of FIG. 13 after the next process step according to the present invention; and

FIG. 15 is a cross-sectional view of the solar cell of FIG. 14 after the next process step according to the present invention.

### DESCRIPTION OF THE PREFERRED EMBODIMENT

Details of the present invention will now be described including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of the actual embodiment nor the relative dimensions of the depicted elements, and are not drawn to scale.

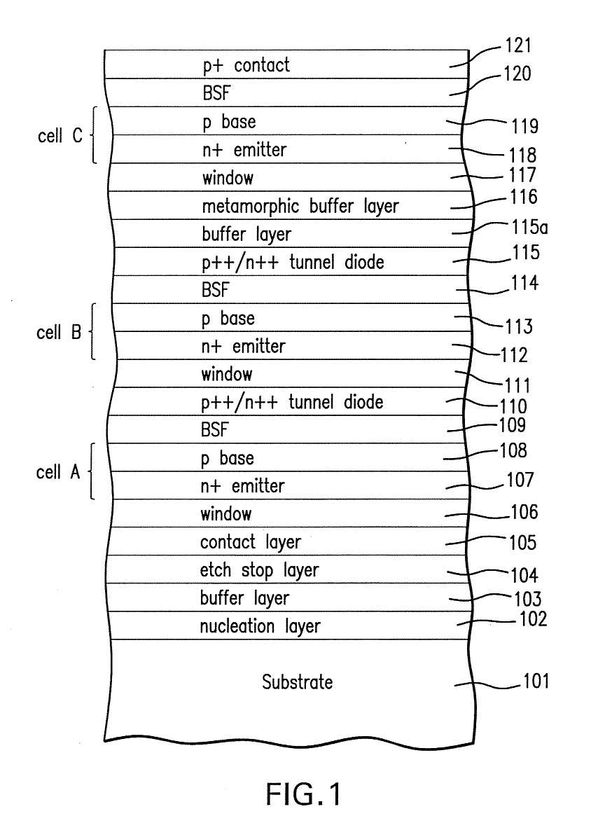

FIG. 1 depicts the multijunction solar cell according to the present invention after formation of the three subcells A, B and C on a substrate. More particularly, there is shown a substrate 101, which may be either gallium arsenide (GaAs), germanium (Ge), or other suitable material. In the case of a Ge substrate, a nucleation layer 102 is deposited on the substrate. On the substrate, or over the nucleation layer 102, a buffer layer 103, and an etch stop layer 104 are further deposited. A contact layer 105 is then deposited on layer 104, and a window layer 106 is deposited on the contact layer. The subcell A, consisting of an n+ emitter layer 107 and a p-type base layer 108, is then deposited on the window layer 106.

It should be noted that the multifunction solar cell structure could be formed by any suitable combination of group III to V elements listed in the periodic table subject to lattice constant and band gap requirements, wherein the group III includes boron (B), aluminum (Al), gallium (Ga), indium (In), and thallium (T). The group IV includes carbon (C), silicon (Si), germanium (Ge), and tin (Sn). The group V includes nitrogen (N), phosphorous (P), arsenic (As), antimony (Sb), and bismuth (Bi).

In the preferred embodiment, the substrate 101 is gallium arsenide, the emitter layer 107 is composed of InGa(Al)P, and the base layer is composed of InGa(Al)P.

The Al term in parenthesis means that Al is an optional constituent, and in this instance may be used in an amount ranging from 0% to 30%.

On top of the base layer 108 is deposited a back surface field (“BSF”) layer 109 used to reduce recombination loss.

The BSF layer 109 drives minority carriers from the region near the base/BSF interface surface to minimize the effect of recombination loss. In other words, a BSF layer 109 reduces recombination loss at the backside of the solar subcell A and thereby reduces the recombination in the base.

On top of the BSF layer 109 is deposited a sequence of heavily doped p-type and n-type layers 110 which forms a tunnel diode which is a circuit element to connect cell A to cell B.

On top of the tunnel diode layers 110 a window layer 111 is deposited. The window layer 111 used in the subcell B also operates to reduce the recombination loss. The window layer 111 also improves the passivation of the cell surface of the underlying junctions. It should be apparent to one skilled in the art, that additional layer(s) may be added or deleted in the cell structure without departing from the scope of the present invention.

On top of the window layer 111 the layers of cell B are deposited: the emitter layer 112, and the p-type base layer 113. These layers are preferably composed of InGaP and In_{0.015}GaAs respectively, although any other suitable materials consistent with lattice constant and band gap requirements may be used as well.

On top of the cell B is deposited a BSF layer 114 which performs the same function as the BSF layer 109. A p++/n++tunnel diode 115 is deposited over the BSF layer 114 similar to the layers 110, again forming a circuit element to connect cell B to cell C. A buffer layer 115a, preferably InGaAs, is deposited over the tunnel diode 115, to a thickness of about 1.0 micron. A metamorphic buffer layer 116 is deposited over the buffer layer 115a which is preferably a compositionally step-graded InGaAlAs series of layers with monotonically changing lattice constant to achieve a transition in lattice constant from cell B to subcell C. The bandgap of layer 116 is 1.5 ev constant with a value slightly greater than the bandgap of the middle cell B.

In one embodiment, as suggested in the Wanless et al. paper, the step grade contains nine compositionally graded steps with each step layer having a thickness of 0.25 micron. In the preferred embodiment, the interlayer is composed of InGaAlAs, with monotonically changing lattice constant.

It should be apparent to one skilled in the art, that additional layer(s) may be added or deleted in the cell structure without departing from the scope of the present invention.

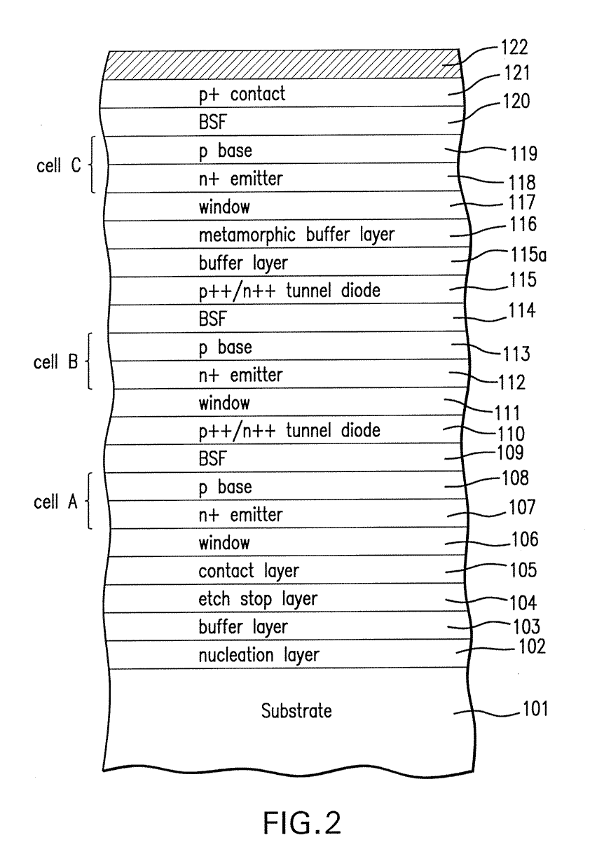

FIG. 2 is a cross-sectional view of the solar cell of FIG. 1 after the next process step according to the present invention in which an ohmic metal contact layer 122 over the p+ semiconductor contact layer 121. The metal is preferably a sequence of Ti/Au or Pd/Ge/Ti/Pd.

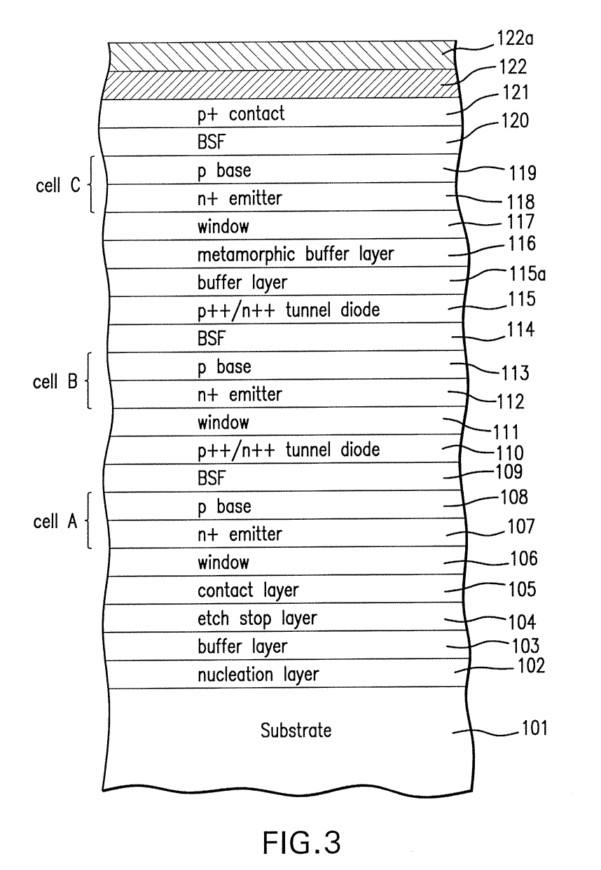

FIG. 3 is a cross-sectional view of the solar cell of FIG. 2 after the next process step according to the present invention in which a metallic contact layer 122a is electroplated over the layer 122. The layer 122a is preferably Ni, NiCo, or AgAu, and is preferably greater than 10 microns in thickness. Other suitable materials known to those skilled in the art can be used as well.

As an example, nickel can be plated onto the wafers in an electrolytic bath. The chemistry, current density, and temperature can be used as control variables to change the stress of the plated nickel. There are other metals (for example, gold and silver) that can also be used in place of nickel. A plating thickness of several microns is possible, which is sufficient to add strength to the thinned wafer. The stress can be changed from compressive values through zero, to tensile strain.

The starting point would be the wafer on which are deposited any needed device layers. These device layers can have some residual strain, which can be adjusted, but only to a limited degree, before device properties might start deteriorating. For the specific case of making thin inverted photovoltaics, a base metal layer, if needed, can be deposited on the top device layer. This seed metal might be needed for ohmic properties, and/or to act as a seed metal for the subsequent plating, etc.

The required plating is done at this juncture, to the device/metal side. As mentioned above, the plating conditions and thickness are chosen to adjust the stress, for final strain control.

This stress can be changed by changing the plating conditions, such as temperature, composition of the plating bath, plating rate, etc. Also, the plated thickness is another variable by which the curvature of the final device/wafer can be controlled.

See, for example, the reference Chopra, K. L., Thin Film Phenomena, McGraw-Hill, New York, 1969, Chapter 5, which states:

Film stress σ=dYₛt²ₛ(1+(Y_{f}t_{f}/Yₛtₛ))/3L²t_{f}(1−μ)

where d=deflection of the substrate+film (thinned wafer with the plated metal), Yₛ and Y_{f} are Young's moduli of the substrate (thinned device layers) and the film (plated metal), respectively, tₛ and t_{f} are the thicknesses of the substrate and the film, respectively, L is the diameter of the substrate, and μ is Poisson's ratio. From this equation, the plated metal stress and thickness can be computed for a particular deflection, or radius of curvature (L²/2d), and the film stress can be adjusted by changing the conditions mentioned above.

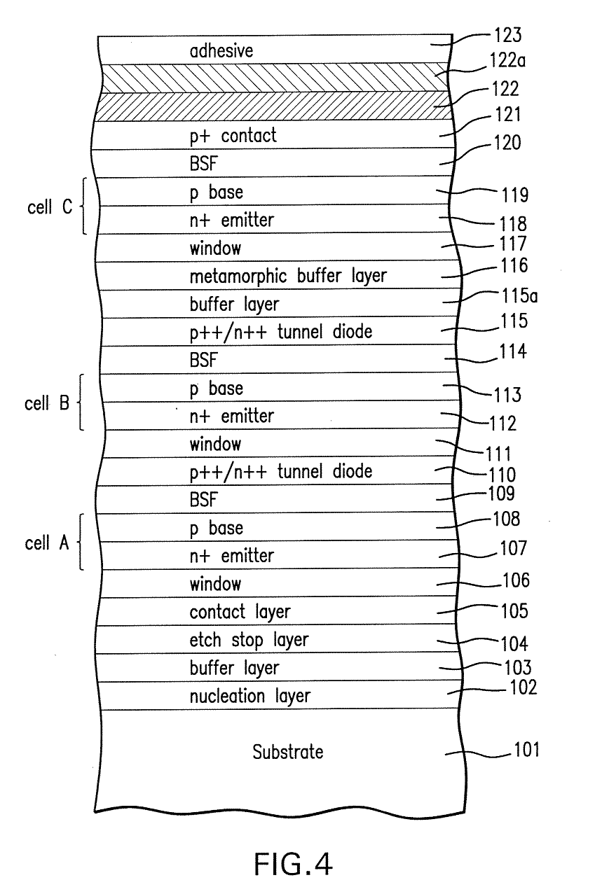

FIG. 4 is a cross-sectional view of the solar cell of FIG. 3 after the next 9 process step in which an adhesive layer 123 is deposited over the metal layer 122a. The adhesive is preferably Dow Corning Q1-4010.

If a rigid carrier is needed during processing, an adhesive, for example, Dow Corning Q1-4010, can be used to attach the metal side of the wafer to the carrier, for example a sapphire substrate with holes. This is done in commercially available wafer equipment that applies a combination of vacuum, pressure, and heat to cure the adhesive. Q1-4010 is a silicone adhesive that is inert to many solvents, acids, bases and other chemicals used in wafer fab. It is also temperature resistant till about 280 degrees C.

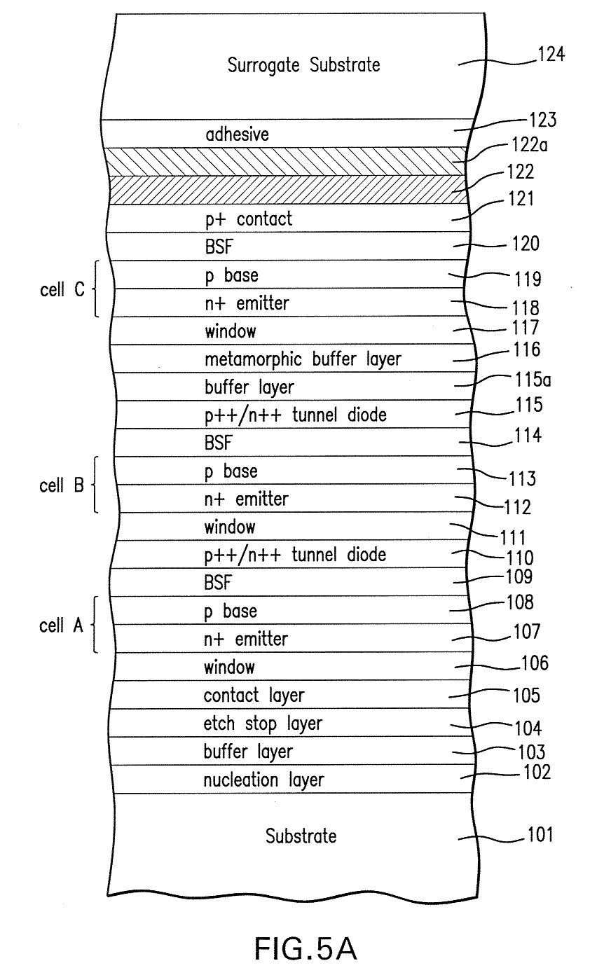

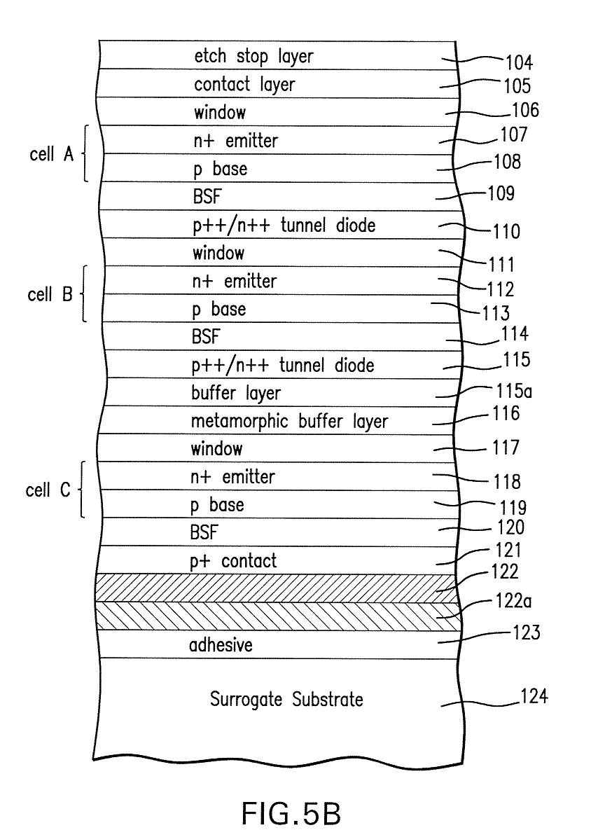

FIG. 5A is a cross-sectional view of the solar cell of FIG. 4 after the next process step according to the present invention in which a surrogate substrate, preferably sapphire, is attached by the adhesive layer 123 to the solar cell. In the preferred embodiment, the surrogate substrate is about 40 mils in thickness, and is perforated with holes about 1 mm in diameter, spaced 4 mm apart, to aid in subsequent removal of the substrate.

Thin (e.g. by grinding, lapping and/or etching) the bulk of the wafer, to reach an etch stop, and/or the device layers, and further process the wafer (e.g. using standard device fab processes). For the specific case of the thin inverted photovoltaic cell, these processes might include, and not be restricted to, lithography, metallization, depositions, etching, etc. The device(s) on the wafer can be tested at this stage, by either contacting the back metal from the front side through suitably etched contact windows, or directly from the back, and the front side metal through front contact pads. The devices can be separated by etching through the semiconductor and metal in between them, or the metal can be cut through after demounting from the carrier.

FIG. 5B is a cross-sectional view of the solar cell of FIG. 4 after the next process step according to the present invention with the surrogate substrate 124 being at the bottom of the figure, and depicting the structure after the original substrate is removed by a sequence of lapping and/or etching steps in which the substrate 101, the nucleation layer 102, and the buffer layer 103 are removed. The choice of etchant is growth substrate dependent.

After processing, as before, the carrier has to be debonded by a solvent. The holes in the sapphire help to speed up the debonding, by increasing access of the solvent to the adhesive. The devices/wafer can be retrieved upon detachment from the sapphire. The plated metal gives additional strength during this process.

The devices now are thin, and have plated metal on the back. Cutting the metal mechanically, through etched streets on the wafer, if needed, can separate them, if separation hasn't been done previously by etching. For the specific case of photovoltaics, the mesa streets can be used to cut through the metal, if the cells need to be separated, and the cells can be interconnected. The cells can be attached to a final flat or curved surface, with or without adhesive (for example, a solar panel), as the devices will be thin enough (microns) to be flexible, with the plated metal giving it the strength to prevent cracking or crumbling. In addition, the stress in the plated metal has compensated any strain in the thin device layers, so that the devices will be fiat after demounting. Excessive curling can lead to cracking of the thin devices, which is prevented by this method. Alternatively, the stress in the plated metal can be used in combination with the strain in the device layers, to get a desired curvature.

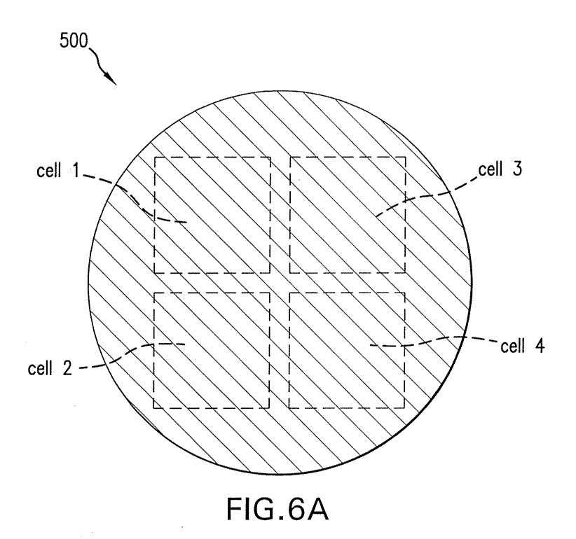

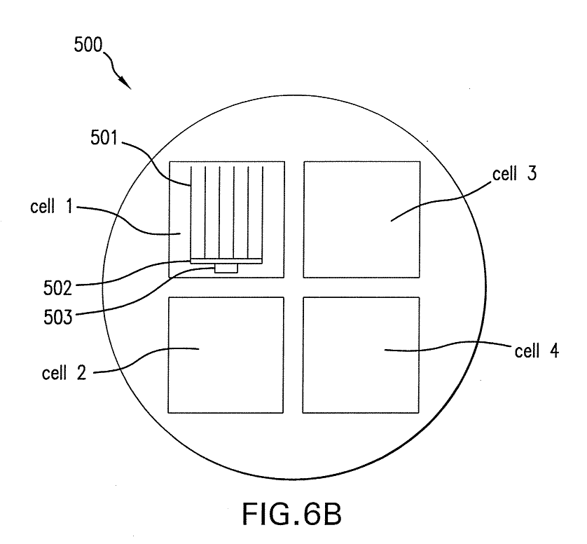

FIG. 6A is a top plan view of a wafer in which the solar cells according to the present invention are implemented.

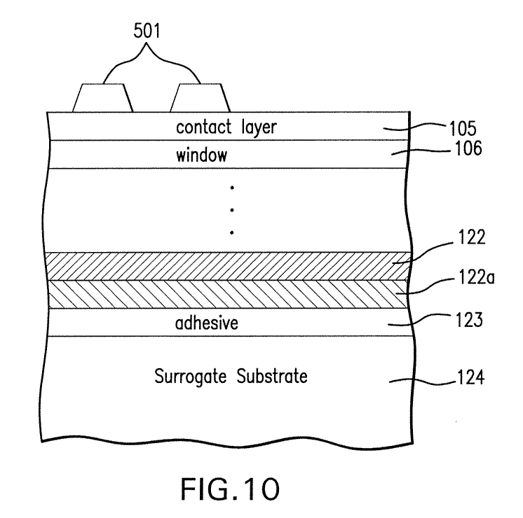

FIG. 6B is a bottom plan view of the wafer with four solar cells shown in FIG. 6A. In each cell there are grid lines 501 (more particularly shown in FIG. 10), an interconnecting bus line 502, and a contact pad 503.

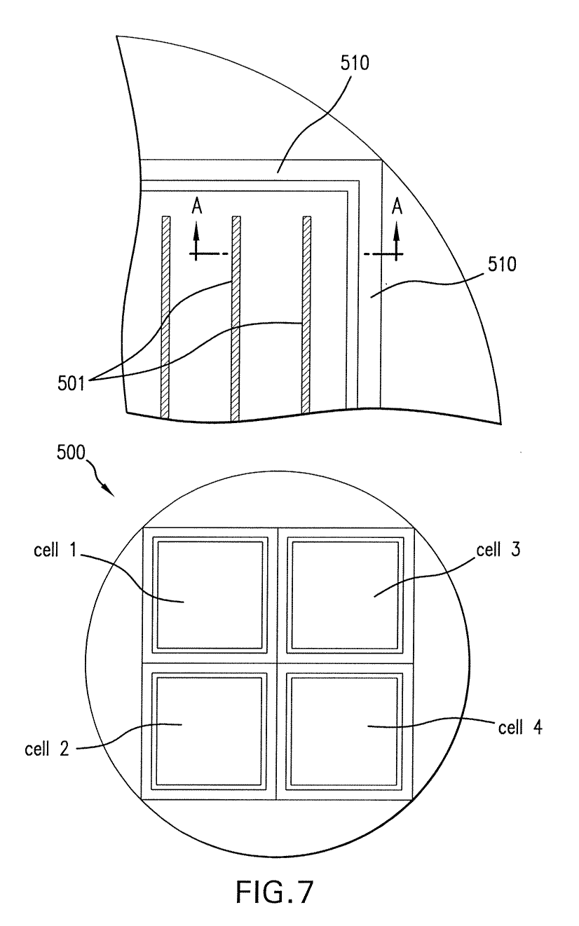

FIG. 7 is a bottom plan view of the wafer of FIG. 6B after the next process step in which a mesa 510 is etched around the periphery of each cell using phosphide and arsenide etchants.

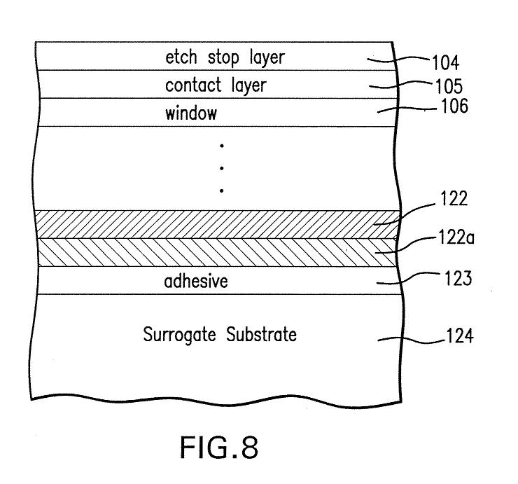

FIG. 8 is a simplified cross-sectional view of the solar cell of FIG. 5B depicting the upper and lower layers.

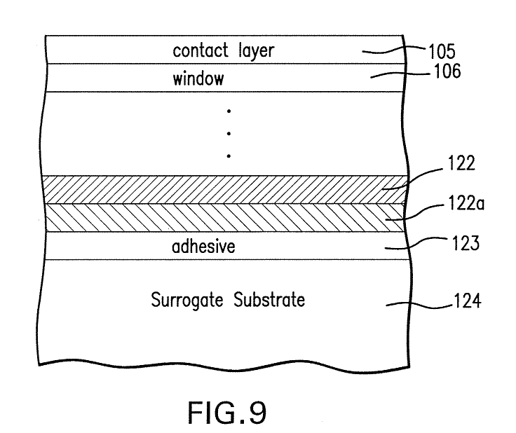

FIG. 9 is a cross-sectional view of the solar cell of FIG. 8 after the next process step according to the present invention in which the etch stop layer 104 is removed by a HCl/H₂O solution.

FIG. 10 is a cross-sectional view of the solar cell of FIG. 9 after the next process step according to the present invention in which a photoresist mask (not shown) is placed over the contact layer 105 as the first step in forming the grid lines 501. The mask 200 is lifted off to form the grid lines 501.

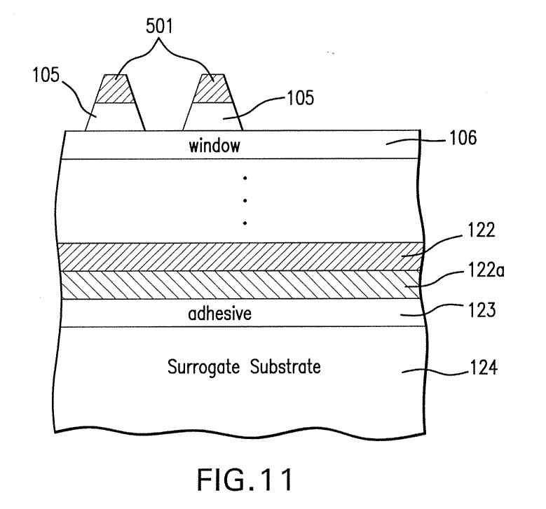

FIG. 11 is a cross-sectional view of the solar cell of FIG. 10 after the next process step according to the present invention in which grid lines 501 are deposited via evaporation and lithographically patterned and deposited over the contact layer 105. The grid lines are used as a mask to etch down the surface to the window layer 106 using a citric acid/peroxide etching mixture.

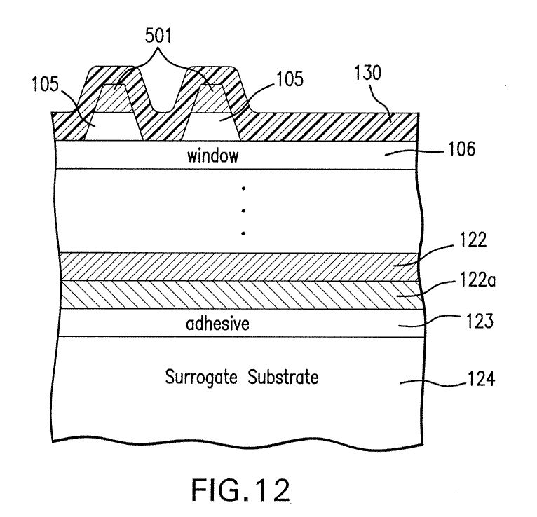

FIG. 12 is a cross-sectional view of the solar cell of FIG. 11 after the next process step according to the present invention in which an antireflective (ARC) dielectric coating layer 130 is applied over the entire surface of the “bottom” side of the wafer with the grid lines 501.

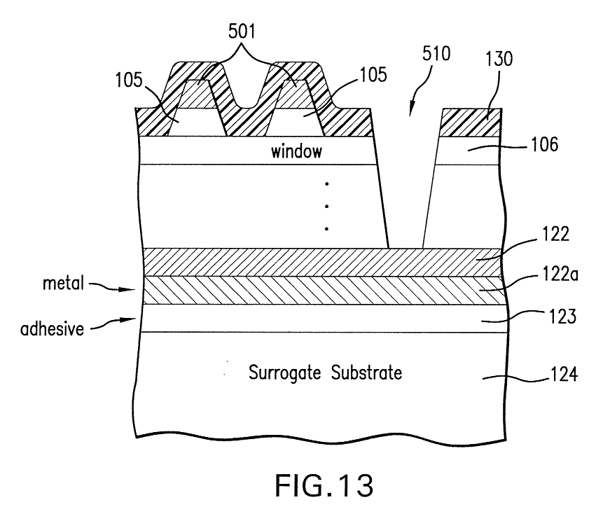

FIG. 13 is a cross-sectional view of the solar cell of FIG. 12 after the next process step according to the present invention in which the mesa 501 is etched down to the metal layer 122 using phosphide and arsenide etchants. The cross-section in the figure is depicted as seen from the A-A plane shown in FIG. 7.

One or more silver electrodes are welded to the respective contact pads.

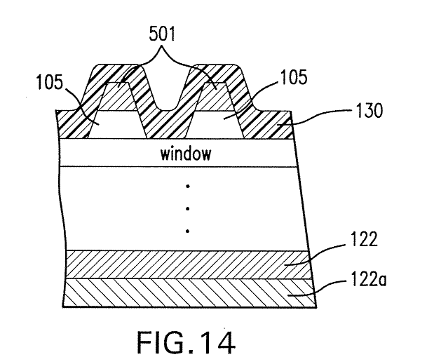

FIG. 14 is a cross-sectional view of the solar cell of FIG. 13 after the next process step according to the present invention after the surrogate substrate 124 and adhesive 123 are removed by EKC 922. Perforations are made over the surface of the substrate, each with a diameter is 0.033 inches and separated by 0.152 inches that allow the flow of etchant through the surrogate substrate 124 to permit its lift off.

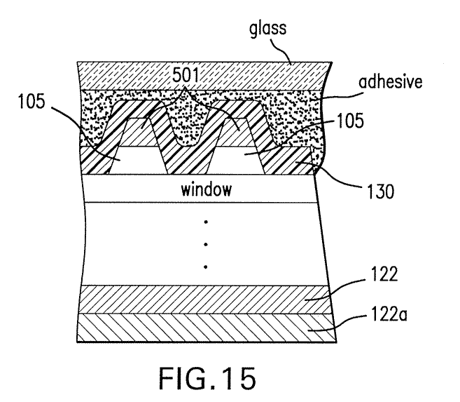

FIG. 15 is a cross-sectional view of the solar cell of FIG. 14 after the next process step according to the present invention in which an adhesive is applied over the ARC layer 130 and a coverglass attached thereto.

It will be understood that each of the elements described above, or two or more together, also may find a useful application in other types of constructions differing from the types of constructions differing from the types described above.

While the invention has been illustrated and described as embodied in a multifunction solar cell, it is not intended to be limited to the details shown, since various modifications and structural changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention and, therefore, such adaptations should and are intended to be comprehended within the meaning and range of equivalence of the following claims.

1. A method of manufacturing a solar cell comprising:
providing a first substrate;
depositing on said first substrate a sequence of layers of semiconductor material forming a solar cell;
forming an ohmic contact layer on said solar cell;
electroplating a metallic contact layer over said ohmic contact layer,
attaching a surrogate substrate to the metallic contact layer; and
removing said first substrate.

2. A method as defined in claim 1, wherein the sequence of layers of semiconductor material forms a multifunction solar cell.

3. (canceled)

4. A method as defined in claim 3, wherein the surrogate substrate is a sapphire wafer.

5. (canceled)

6. A method as defined in claim 5, further comprising attaching said solar cell to a glass supporting member.

7. A method as defined in claim 1, wherein said step of depositing a sequence of layers of semiconductor material includes forming a first solar subcell on said substrate having a first band gap; forming a second solar subcell over said first subcell having a second band gap smaller than said first band gap; forming a grading interlayer over said second subcell having a third band gap larger than said second band gap; forming a third solar subcell having a fourth band gap smaller than said second band gap such that said third subcell is lattice mismatched with respect to said second subcell.

8. A method of manufacturing a solar cell as defined in claim 1, wherein said first substrate is composed of GaAs.

9. A method of manufacturing a solar cell as defined in claim 7, wherein said first solar subcell is composed of an InGa(Al)P emitter region and an InGa(Al)P base region.

10. A method of manufacturing a solar cell as defined in claim 7, wherein said second solar subcell is composed of an InGaP emitter region and an In0.015GaAs base region.

11. A method of manufacturing a solar cell as defined in claim 7, wherein said grading interlayer is composed of InGaAlAs.

12. A method of manufacturing a solar cell as defined in claim 7, wherein the grading interlayer is composed of a plurality of layers with monotonically increasing lattice constant.

13. A method as defined in claim 1, wherein said ohmic contact layer is evaporated.

14. A method as defined in claim 1, wherein the composition of said ohmic contact layer is selected from the group consisting of: Pd, Ge, Ti, Pd and TiAu.

15. A method as defined in claim 1, wherein said ohmic contact layer is approximately 2000 Angstroms in thickness.

16. A method as defined in claim 1, wherein said metallic contact layer is selected from the group consisting of: Ni, NiCo, and AgAu.

17. A method as defined in claim 1, wherein said metallic contact layer is greater than 10 microns in thickness.

18. A method as defined in claim 1, further comprising adjusting the strain of said metallic contact layer to compensate for the strain in the sequence of layers, so as to control the curvature of the thin wafer solar cell.

19. A solar cell comprising:
a semiconductor body having a sequence of layers including a first solar subcell having a first band gap;
a second solar subcell disposed over the first subcell and having a second band gap smaller than the first band gap;
a grading interlayer disposed over the second subcell and having a third band gap larger than the second ban gap;
a third subcell disposed over the interlayer such that the third solar subcell is lattice mismatched with respect to the second subcell and has a fourth band gap smaller than the third band gap; and
an electroplated contact layer disposed over said third subcell.

20. A solar cell as defined in claim 19, wherein said semiconductor body is a thin film structure having a thickness about 12 microns.
